(19) United States
(12) Patent Application Publication
(10) Pub. No.: US 2007/0176186 A1
(43) Pub. Date: Aug. 2, 2007

(54) Light emitting device for enhancing brightness

(76) Inventor: San Bao Lin, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/653,315

(22) Filed: Jan. 16, 2007

(30) Foreign Application Priority Data
Jan. 27, 2006 (TW) 095103280

(51) Int. Cl. H01L 33/00

(52) U.S. Cl. 257/79

(57) ABSTRACT

A light emitting device for enhancing brightness is provided, comprising a first contact and a second contact provided on a light emitting diode and respectively connected with a first conductive lead and a second conductive of a transparent submount such that can achieve the purpose of supplying power for the light emitting diode, and a reflective layer disposed on other surface of the transparent submount, wherein a downward light generated from the light emitting diode can pass through the light emitting diode and the transparent submount to the outside of the light emitting device. Therefore, the brightness of the light emitting device can be enhanced.

### FIELD OF THE INVENTION

The present invention relates to a light emitting device, and more particularly a light emitting device for enhancing brightness, comprising a reflective layer disposed on the transparent submount to enhance the brightness of the light emitting device.

### BACKGROUND

The light emitting diode (LED) has advantages of long lifetime, small size, short reaction-time, and without radiation, hence it has come to play a critical role in numerous application, such as indicator lights, lamps, traffic lights, flat-panel displays, optical communications and so on.

Referring to FIG. 1 is a cross sectional view of the prior art light emitting device. The light emitting device 10 comprises a light emitting diode 13 disposed on a submount 19, wherein the light emitting diode 13 comprises a first material layer 131 and a second material layer 133 attached as a stack. A first contact 171 is disposed on a partial surface of the first material layer 131, and a second contact 173 is disposed on a partial surface of the second material layer 133. The first contact 171 and the second contact 173 are respectively electrical connection with the first conductive lead 191 and the second conductive lead 193 of the submount 19 by a conductive adhesion layer 18, therefore a power signal can be supplied for the light emitting diode 13.

The first material layer 131 and the second material layer 133 are respectively an N-type semiconductor material and a P-type semiconductor material, thus, a PN junction is formed by sandwiching between the N-type semiconductor material and the P-type semiconductor material spontaneously. The light emitting diode 13 can be emitted, such as a top light L1 and a downward light L2, while a voltage is applied between the first contact 171 and the second contact 173.

Furthermore, a reflective layer 15 is disposed on the surface of the light emitting diode 13 to extract the emitting light, hence, the brightness of the light emitting diode 13 can be enhanced. For example, the top light L1 can pass through the first material layer 131 and the transparent substrate 11 to the outside of the light emitting diode 13, besides, a reflective layer 15 disposed on the surface of the second material layer 133 is used to reflect the downward light L2 to the outside of that and the brightness of the light emitting device 10 can be enhanced.

Practically, the light emitting diode 13 is always under a high temperature environment during the light emitting process or the fabricating process. For example, the high temperature is generated during the fabricating process or the light emitting process, and then the heat may damage the structure of the second material layer 133 and the reflective layer 15, therefore, the refection efficiency of the reflective layer 15 is decreased and the brightness of the light emitting device 10 is limited.

The reflective layer 15 is used to reflect the downward light L2 that passes through the first material layer 131, the PN junction and the second material layer 133 to the outside of the light emitting device 10, thus, the brightness of the downward light L2 is decreased. Besides, a partial downward light L2 may suffer multiple total internal reflections at the walls of high refractive index semiconductor medium, such as the first material layer 131, second material layer 133, and the PN junction. As a result, the brightness of the downward light L2 is decreased, which further causes the poor extraction efficiency.

### SUMMARY OF THE INVENTION

Accordingly, the key point of the present invention discloses a novel light emitting device, not only enhancing the extraction efficiencies of the downward light, but also avoiding poor brightness of the light emitting device.

It is a primary object of the present invention to provide a light emitting device for enhancing the brightness capable of solving the problems encountered by the above mentioned prior art.

It is a secondary object of the present invention to provide a light emitting device for enhancing brightness, wherein the reflective layer does not contact with the light emitting diode for avoiding the intermixing of materials of the reflective layer and the second material layer, and maintaining the structural integrity of the reflective layer.

It is another object of the present invention to provide a light emitting device for enhancing brightness, wherein the transparent submount is made of a high thermal conductivity material for extracting the heat generating in the light emitting process of the light emitting diode advantageously.

It is another object of the present invention to provide a light emitting device for enhancing brightness, wherein the reflective layer disposed on the transparent submount can be used for extracting the downward light, and total internal reflection of downward light may be not occur between the first material layer and the second material layer for preventing the brightness of the downward light decreasing.

It is another object of the present invention to provide a light emitting device for enhancing brightness, wherein a transparent layer is disposed between the light emitting diode and the transparent submount to improve the extraction efficiency of downward light into the transparent submount.

To achieve the above mentioned objects, the present invention provides a light emitting device for enhancing brightness, comprising: at least one light emitting diode, comprising a first material layer and a second material layer attached as a stack, at least one first contact disposed on the first material layer, and at least one second contact disposed on the second material layer; a transparent submount, comprising at least one first conductive lead disposed on the transparent submount and connected with the first contact, and at least one second conductive lead disposed on the transparent submount and connected with the second contact; and a reflective layer disposed on the bottom surface of the transparent submount.

Further, the present invention further provides a light emitting device for enhancing brightness, comprises at least one light emitting diode disposed on the top surface of a transparent submount, and a reflective layer disposed on the bottom surface of the transparent submount.

### BRIEF DESCRIPTION OF DRAWINGS

FIG. 1 is a cross sectional view of a prior art light emitting device.

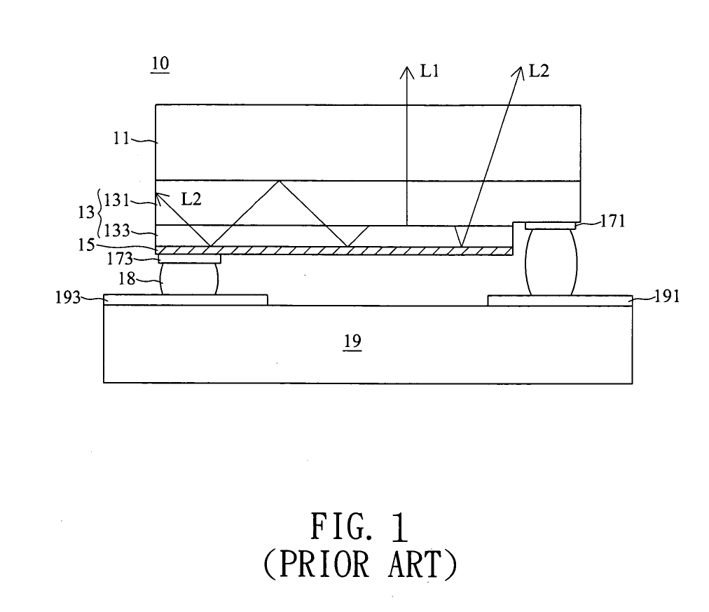

FIG. 2 is a cross sectional view of an embodiment of the present invention.

FIG. 3 is a cross sectional view of another embodiment of the present invention.

FIG. 4 is a cross sectional view of another embodiment of the present invention.

FIG. 5 is a cross sectional view of another embodiment of the present invention.

### DETAILED DESCRIPTION

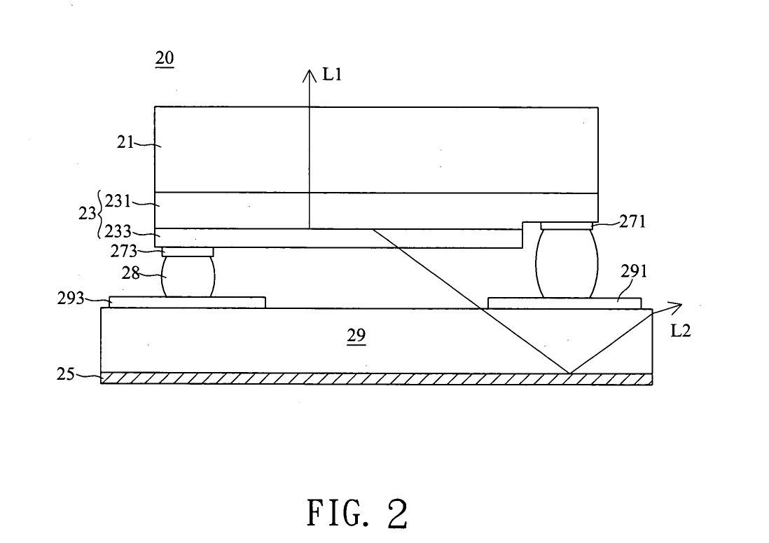

Referring to FIG. 2 is a cross section view of an embodiment of the present invention a light emitting device. The light emitting device 20 comprises at least one light emitting diode 23 disposed on the top surface of a transparent submount 29, and a reflective layer 25 disposed on the bottom surface of the transparent submount 29. The light emitting diode 23 comprises a first material layer 231 and a second material layer 233 attached as a stack. For example, the first material layer 231 and the second material layer 233 are respectively an N-type semiconductor material and a P-type semiconductor material, and a PN junction is formed by sandwiching between the N-type and P-type semiconductor material spontaneously.

The transparent submount 29 is made of a transparent material, and the thermal expansion coefficient of the transparent submount 29 and the light emitting diode 23 are similar for forming the light emitting diode 23 on the transparent submount 29 advantageously, such that the light emitting diode 23 and the transparent submount 29 will not separate easily while the temperature is raise. Besides, the transparent submount 29 can be made of a high thermal conductivity material for extracting the heat generating during the light emitting process from light emitting device 20 advantageously. For example, the thermal conductivity of the transparent submount 29 is greater than 35 w/m·k, therefore, the transparent submount 29 can be made of sapphire or SiC.

At least one first contact 271 disposed on the surface of the first material layer 231 is connected with the first conductive lead 291 of the transparent submount 29 through the conductive adhesion layer 28, and at least one second contact 273 disposed on the surface of the second material layer 233 is connected with the second conductive lead 293 of the transparent submount 29 through the conductive adhesion layer 28. The power is supplied for the light emitting diode 23 through the first conductive lead 291 and the second conductive lead 293 to achieve the purpose of emitting light. For example, the conductive adhesion layer 28 is a solder ball, a eutectic, a gold ball to gold, or a gold ball to metal

A reflective layer 25 is disposed on the transparent submount 29. For example, the reflective layer 25 is disposed on the bottom surface of the transparent submount 29, and the first conductive lead 291 and the second conductive lead 293 are disposed on the top surface of the transparent submount 29. Therefore, the top light L1 generated by the light emitting diode 23 can directly pass through the first material layer 231 and transparent substrate 23 to the outside of the light emitting device 20. The reflective layer 25 disposed on the transparent submount 29 can be used to reflect the downward light L2 that passes through the second material layer 233 and the transparent submount 29 to the outside of the light emitting device 20.

Comparing with prior art structure, the reflective layer 25 is disposed on the transparent submount 29 to prevent the intermixing of materials of the second material layer 233 of the light emitting diode 23 and the reflective layer 25, and maintain structural integrity of the reflective layer 25, hence, the extraction efficiency of the downward light L2 generated by the light emitting diode 23 can be improved. The reflective layer 25 is used to reflect the downward light L2 extracted through the transparent submount 29 to avoid total internal reflection of the downward light L2 occurring between the first material layer 131 and the second material layer 133 as the prior art structure, and the extraction efficiency and brightness of the downward light L2 can be improved.

The reflective layer 25 can be a metal layer, such as aluminum, silver and so on. In another embedment of the invention, the reflective layer 25 can be a multilayer reflector or a photonic crystal. For example, the reflective layer 25 is made of TiO₂, SiO₂, Al₂O₃ or the combination thereof to improve the reflective efficiency of that.

The material of the light emitting diode 23 can be nitrides, ternary compound, or quaternary compound. The transparent substrate 21 is made of a transparent material, such as sapphire, SiC, GaP, GaAsP, ZnSe, ZnS, or ZnSeS.

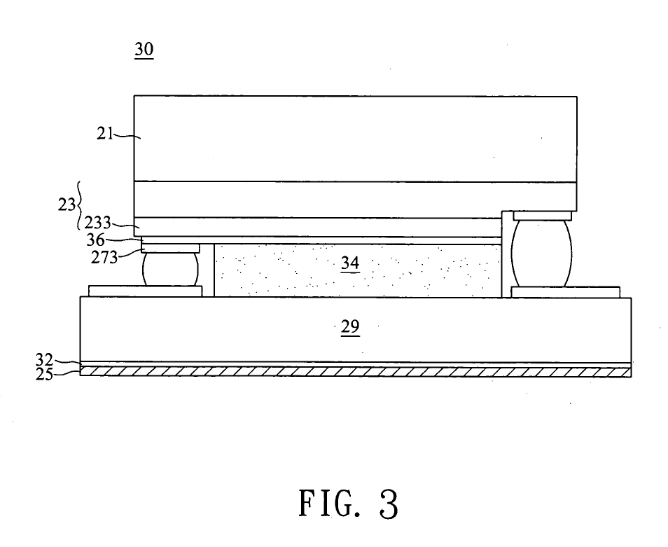

Referring to FIG. 3 is a cross section view of another embodiment of the present invention a light emitting device. The light emitting device 30 comprises a light emitting diode 23 disposed on the transparent submount 29 in flip chip configuration. The second material layer 233 of the light emitting diode 23 is electrical connection with the second conductive lead 273 by a transparent conductive layer 36. Therefore, the power signal can be uniformly distributed on the second material layer 233 to enhance the brightness area and the uniformity of the light emitting diode 23.

A transparent layer 34 is disposed between the light emitting diode 23 and the refractive index of transparent submount 29 matches that of the light emitting diode 23 and the transparent submount 29, and to enhance the efficiency of downward light L2 from the light emitting diode 23 into the transparent submount 29 and the extraction efficiency of the downward light L2. For example, n1 that is the refractive index of the transparent layer 34 is between n2 that is the refractive index of the second material layer 233 (or transparent conductive layer 36) and n3 that is the refractive index of the transparent submount 29. In another embodiment, the material of the transparent layer 34 and the transparent submount 29 are the same.

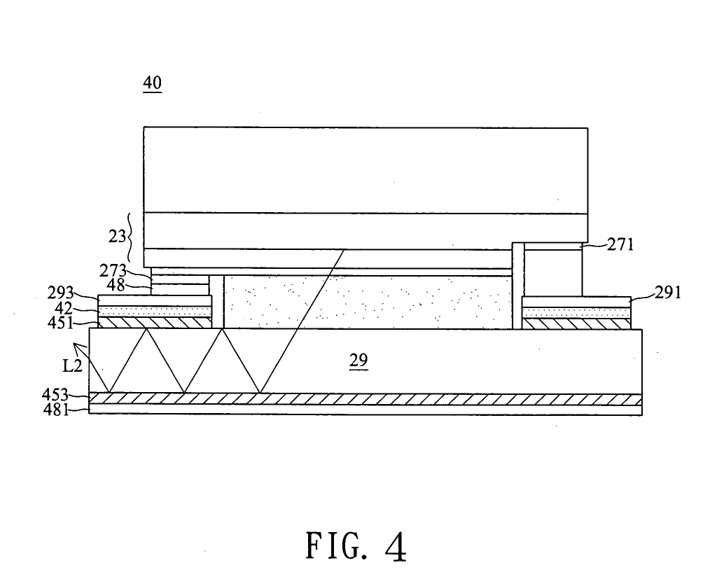

An adhesion layer 32 is disposed between the reflective layer 25 and the transparent submount 29. The reflective layer 25 made of a metal can easily adhere to the transparent submount 29 by the adhesion layer 32. For example, the adhesion layer 32 is made of Al₂O₃ or SiO₂ Referring to FIG. 4 is another embodiment of the present invention. The light emitting device 40 comprises a light emitting diode 23 of which first contact 271 and second contact 273 are respectively disposed on the first conductive lead 291 and the second conductive lead 293 of the transparent submount 29 by a conductive adhesion layer 48; for example, the conductive adhesion layer 48 can be a solder ball, a eutectic, a gold ball to gold, or a gold ball to metal. A barrier layer 42 and a first reflective layer 451 are disposed under the first conductive lead 291 and the second conductive lead 293 in turn. In other words, the barrier layer 42 and the first reflective layer 451 are disposed between the first conductive lead 291 and the transparent submount 29, and between the second conductive lead 293 and the transparent submount 29.

A second reflective layer 453 is disposed on the bottom surface of the transparent submount 29, and then the downward light L2 suffers total internal reflections between the first reflective layer 451 and the second reflective layer 453 until extracting the downward light L2 to the outside of the light emitting device 40. The brightness of the downward light L2 cannot be easily decreased to enhance the extraction efficiency of that, even if total internal reflection of the downward light L2 occurs in the transparent submount 29, since the transparent submount 29 is made of a low refractive index material. The material of the first reflective layer 451 and the second reflective layer 453 are the same.

In the device illustrated in FIG. 4, a barrier layer 42 is disposed between the first reflective layer 451 and the first conductive lead 291, and between the first reflective layer 451 and the second conductive lead 293. In another embodiment of the invention, the barrier layer 42 can be omitted, and then the first reflective layer 451 is disposed on the first conductive lead 291 and the second conductive lead 293. The first conductive lead 291 and the second conductive lead 293 can be made of a reflective material to achieve the purpose of reflecting the downward light L2 without the first reflective layer 451 and the barrier layer 42.

The second reflective layer 453 is disposed on the bottom surface of the transparent submount 29, and a bonding layer 481 is disposed on the second reflective layer 29 for connecting the light emitting device 40 and other device advantageously. The range of disposing the first reflective layer 451 can be extended from the vertical extension place of the first conductive lead 291, the second conductive lead 293 and/or the barrier layer 42.

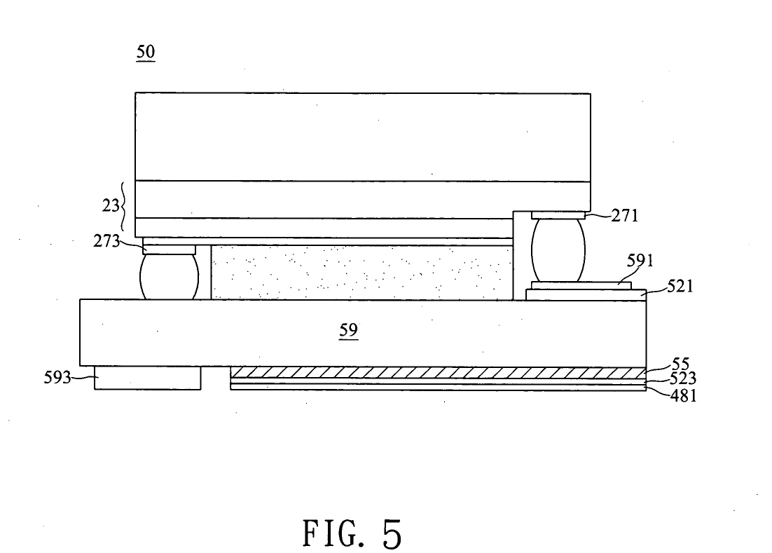

Referring to FIG. 5 is a cross section view of another embodiment of the present invention. The light emitting device 50 comprises at least one light emitting diode 23 disposed on the transparent submount 59. The transparent submount 59 is made of a transparent conductive material, such as SiC, therefore the power is supplied for the first contact 271 or the second contact 273 through the transparent submount 59.

In the embodiment of the invention, the first conductive lead 591 and the second conductive lead 593 are formed on different surface of the transparent submount 59. Besides, the first conductive lead 591 is electrical connection with the first contact 271, and the second conductive lead 593 is electrical connection with the second contact 273. For example, the second conductive lead 593 and the reflective layer 55 are disposed on the bottom surface of the transparent submount 59, and a isolating layer 521 and the first conductive lead 591 are disposed on the top surface of the transparent submount 59 in turn.

The power signal is transmitted to the second contact 273 through the second conductive lead 593 and the transparent submount 59. The isolating layer 521 is disposed between the first conductive lead 591 and the transparent submount 59, so the power signal in the transparent submount does not transmit to the first conductive lead 591 to avoid short circuit in the light emitting diode 23.

In another embedment of the invention, the position of the first conductive lead 591 and the second conductive lead 593 can be exchanged. For example, the first conductive lead 591 and the reflective layer 55 are dispose on the bottom surface of the transparent submount 59, and the isolating layer 521 and the second conductive lead 593 are disposed on the top surface of the transparent submount 59 in turn.

A barrier layer 523 and a bonding layer 481 are disposed on the reflective layer 55 in turn. In other words, the barrier layer 523 is disposed between the reflective layer 55 and the bonding layer 481 to maintain the structural integrity and the reflective efficiency of the reflective layer 55.

In all above embodiment of the invention, the transparent substrate 21 disposed on the light emitting diode 23 can be removed.

The foregoing description is merely one embodiment of present invention and not considered as restrictive. All equivalent variations and modifications in process, method, feature, and spirit in accordance with the appended claims may be made without in any way from the scope of the invention.

1. A light emitting device for enhancing brightness, comprising:
at least one light emitting diode, comprising a first material layer and a second material layer attached as a stack, at least one first contact disposed on said first material layer, and at least one second contact disposed on said second material layer;
a transparent submount, comprising at least one first conductive lead disposed on said transparent submount and connected with said first contact, and at least one second conductive lead disposed on said transparent submount and connected with said second contact; and
a reflective layer disposed on the bottom surface of said transparent submount.

2. The light emitting device of claim 1, further comprising a transparent layer disposed between said light emitting diode and said transparent submount.

3. The light emitting device of claim 2, wherein the refractive index of said transparent layer is between said second material layer and said transparent submount.

4. The light emitting device of claim 2, wherein the material of said transparent layer and said transparent submount are the same.

5. The light emitting device of claim 1, further comprising a transparent conductive layer disposed between said second material layer and said second contact.

6. The light emitting device of claim 1, wherein said reflective layer can be selectively as one of a metal layer, a multilayer reflector and a photonic crystal.

7. The light emitting device of claim 1, wherein said first contact and said second contact of said light emitting device respectively connect with said first conductive lead and said second conductive lead through a conductive adhesion layer.

8. The light emitting device of claim 1, further comprising a bonding layer disposed on said reflective layer.

9. The light emitting device of claim 8, further comprising a barrier layer disposed between said reflective layer and said bonding layer.

10. The light emitting device of claim 1, further comprising a first reflective layer disposed between said transparent submount and said first conductive lead, and between said transparent submount and said second conductive lead.

11. The light emitting device of claim 10, further comprising a barrier layer disposed between said first reflective layer and first conductive lead, and between said first reflective layer and second conductive lead.

12. The light emitting device of claim 1, wherein said first conductive lead and said second conductive lead are disposed on the top surface of said transparent submount and connected with said first contact and said second contact of said light emitting diode, said reflective layer is disposed on the bottom surface of said transparent submount.

13. The light emitting device of claim 1, further comprising an isolating layer disposed between said first conductive lead and said transparent submount, wherein said transparent submount is made of a transparent conductive material, said first conductive lead is disposed on the top surface of said transparent submount, and said second conductive lead and said reflective layer are disposed on the bottom surface of said transparent submount, said second conductive lead is electrically connected with said second contact through said transparent submount.

14. The light emitting device of claim 1, further comprising an isolating layer disposed between said second conductive lead and said transparent submount, wherein said transparent submount is made of a transparent conductive material, said second conductive lead is disposed on the top surface of said transparent submount, and said first conductive lead and said reflective layer are disposed on the bottom surface of said transparent submount, said first conductive lead is electrically connected with said first contact through said transparent submount.

15. The light emitting device claim 1, further comprising a transparent substrate disposed on said light emitting diode.

16. The light emitting device of claim 1, wherein said transparent submount can be selectively as one of SiC and sapphire.

17. The light emitting device of claim 1, further comprising an adhesion layer disposed between said reflective layer and said transparent submount.

18. A light emitting device for enhancing brightness comprises at least one light emitting diode disposed on the top surface of a transparent submount, and a reflective layer disposed on the bottom surface of said transparent submount.

19. The light emitting device of claim 18, further comprising a transparent layer disposed between said light emitting diode and said transparent submount.

20. The light emitting device of claim 18, further comprising a transparent substrate disposed on said light emitting diode.
